(19) United States
(12) Patent Application Publication
(10) Pub. No.: US 2022/0256742 A1
(43) Pub. Date: Aug. 11, 2022

(54) HEAT DISSIPATION STRUCTURE AND HEAT DISSIPATION MODULE

(71) Applicant: PAN YU-HSIANG, Taipei City (TW)

(72) Inventor: PAN YU-HSIANG, Taipei City (TW)

(21) Appl. No.: 17/667,046

(22) Filed: Feb. 8, 2022

(30) Foreign Application Priority Data
Feb. 9, 2021 (TW) TW 110105023

(51) Int. Cl. H05K 7/20

(52) U.S. Cl. CPC H05K 7/20472; H05K 7/20454

(57) ABSTRACT

A heat dissipation structure includes a heat dissipation body and at least one cup-like structure. The heat dissipation body has a first surface and a second surface, wherein the first surface is adapted to couple with an electronic component. The cup-like structure is formed on the second surface of the heat dissipation body and includes a bottom and a curved structure. The curved structure connects the bottom and the second surface, and forms a closed contour at a junction with the second surface. A heat dissipation module includes the heat dissipation structure and a heat-conducting plate, wherein two sides of the heat-conducting plate adhere to the first surface and the electronic component, respectively.

### BACKGROUND OF THE DISCLOSURE

### 1. Field of the Disclosure

The present invention relates generally to a heat dissipation structure and a heat dissipation module, and more particularly to a heat dissipation structure and a heat dissipation module adapted for electronic components.

### 2. Description of the Prior Art

With the rapid development in all kinds of technology industries in recent years, various electronic products such as smartphones, notebooks, and tablet PCs have been widely used in people's daily lives. The CPUs (central processing units) and GPUs (graphics processing units) used in electronic products generate heat while operating. A typical heat dissipation structure is to set up multiple heat dissipation fins on a heat dissipation body coupled with an electronic product to dissipate heat from the electronic product.

However, the design and development trends of electronic products of major brands in the market are becoming thinner and smaller, and the heat dissipation structure with convex fins has a large size, which is a disadvantage for designing the looks and sizes of electronic products.

### SUMMARY OF THE DISCLOSURE

The present invention provides a heat dissipation structure and a heat dissipation module adapted for an electronic component, aiming to solve the problem mentioned above.

In an embodiment, the present invention provides a heat dissipation structure adapted for an electronic component, wherein the heat dissipation structure includes a heat dissipation body and at least one cup-like structure. The heat dissipation body has a first surface and a second surface opposite to the first surface, wherein the first surface is adapted to couple with the electronic component. The at least one cup-like structure is formed on the second surface of the heat dissipation body, wherein the at least one cup-like structure includes a bottom and a curved structure. The curved structure connects the bottom and the second surface of the heat dissipation body, wherein the curved structure forms a contour at a junction with the second surface, and the contour is closed.

In another embodiment, the present invention provides a heat dissipation structure adapted for an electronic component, wherein the heat dissipation structure includes a heat dissipation body and at least one cup-like structure. The heat dissipation body has a first surface and a second surface opposite to the first surface, wherein the first surface is adapted to couple with the electronic component. The at least one cup-like structure is formed on the second surface of the heat dissipation body, wherein the at least one cup-like structure is substantially a hemispherical structure.

In another embodiment, the present invention provides a heat dissipation module adapted for an electronic component, which includes the heat dissipation structure mentioned above and a heat-conducting plate. The heat-conducting plate has a first side and a second side opposite to the first side, wherein the first side of the heat-conducting plate adheres to the first surface of the heat dissipation body, and the second side of the heat-conducting plate adheres to the electronic component.

In summary, the heat dissipation structure provided in the present invention includes a heat dissipation body and a cup-like structure, wherein the cup-like structure is formed on a second surface of the heat dissipation body to increase a surface area for heat dissipation, whereby to improve the cooling effect of the heat dissipation structure. The above and other technical contents, features, and effects will be clearly expressed in the following detailed descriptions of embodiments along with the drawings.

### BRIEF DESCRIPTION OF THE DRAWINGS

The present invention will be best understood by referring to the following detailed description of one illustrative embodiment in conjunction with the accompanying drawings, in which

FIG. 1 is a schematic view of the heat dissipation structure of an embodiment of the present invention;

FIG. 2 is a schematic view of the heat dissipation structure of the embodiment of the present invention;

FIG. 3 is a schematic view showing part of the heat dissipation structure of the embodiment of the present invention;

FIG. 4 is a schematic view showing part of the heat dissipation structure of another embodiment of the present invention;

FIG. 5 is a schematic view showing part of the heat dissipation structure of yet another embodiment of the present invention; and

FIG. 6 is sectional schematic view showing part of the heat dissipation structure of the yet another embodiment of the present invention.

### DETAILED DESCRIPTION

To help those skilled in the art to further understand the present invention, preferred embodiments of the invention are set forth below, together with the accompanying drawings, which describe in detail the composition and the intended effect of the present invention. It should be noted that the accompanying drawings are simplified schematic drawings and therefore only show the components and combinations related to the present invention to provide a more straightforward description of the essential structures or methods of implementations of the present invention, while the actual components and configurations may be more complicated. In addition, for illustration purposes, the components shown in the accompanying drawings of the present invention are not drawn to the same scale as the actual numbers, shapes, and sizes of the implementations, and their detailed scale may be adjusted according to design requirements.

The directional terms mentioned in the following examples, such as “up”, “down”, “left”, “right”, “front”, and “rear”, are merely references to the direction in the accompanying drawings. Thus, the directional terms used are for illustrative purposes and are not intended to limit the present invention.

Although the terms “first”, “second”, “third”, etc., may be used to describe a variety of components, the components are not limited by these terms. These kinds of terms are used only to distinguish one component from other components in the specification, and their sequences may be different in the claims, in the order in which the components are claimed. Therefore, in the following descriptions, a first some component may be a second some component in the claims.

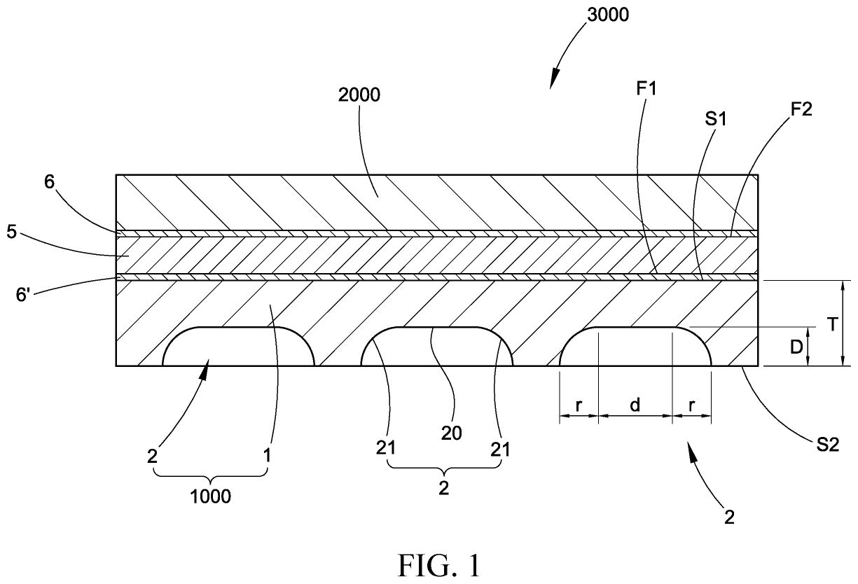

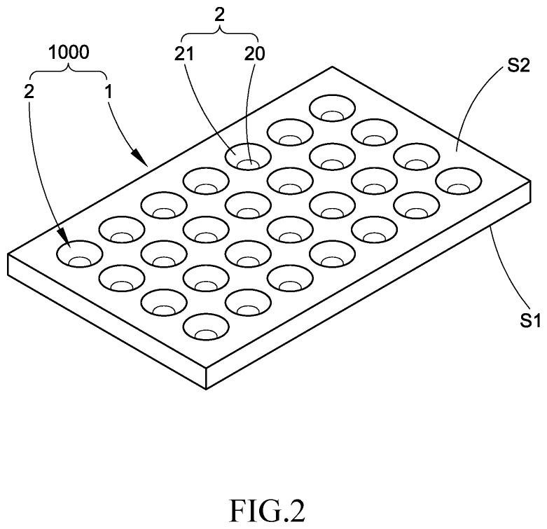

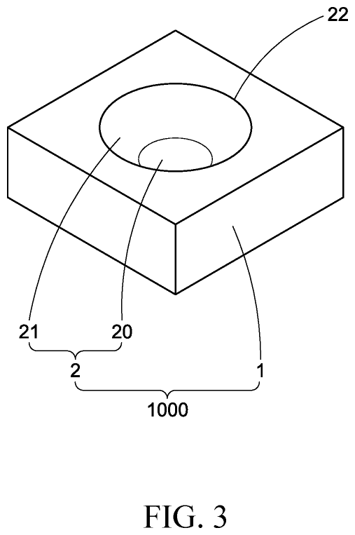

A heat dissipation module 3000 of a first embodiment of the present invention is shown in FIG. 1. The heat dissipation module 3000 is adapted for an electronic component 2000, and includes a heat dissipation structure 1000 and a heat-conducting plate 5, wherein the heat-conducting plate 5 has a first side F1 and a second side F2 opposite to the first side F1. The heat dissipation structure 1000 of the first embodiment of the present invention is shown in FIG. 2, and part of the heat dissipation structure 1000 of the first embodiment of the present invention is shown in FIG. 3. The heat dissipation structure 1000 includes a heat dissipation body 1 and at least one cup-like structure 2, wherein the heat dissipation body 1 has a first surface S1 and a second surface S2 opposite to the first surface S1. The first side F1 of the heat-conducting plate 5 adheres to the first surface S1 of the heat dissipation body 1, and the second side F2 of the heat-conducting plate 5 adheres to the electronic component 2000. In the current embodiment, the electronic component 2000 can be a central processing unit (CPU) or a graphics processing unit (GPU) of an electronic device such as a smartphone, a notebook PC, a tablet PC, etc. However, this is not a limitation of the present invention. In other words, the heat dissipation module 3000 or the heat dissipation structure 1000 provided in the present invention could be also adapted for heat dissipation of a desktop computer or other devices, depending on actual requirements.

In practice, the heat dissipation module 3000 could further include another first thermal adhesive 6′ and a second thermal adhesive 6, wherein the first side F1 of the heat-conducting plate 5 adheres to the first surface S1 of the heat dissipation body 1 through the first thermal adhesive 6′, and the second side F2 of the heat-conducting plate 5 adheres to the electronic component 2000 through the second thermal adhesive 6.

In the current embodiment, the cup-like structure 2 of the heat dissipation structure 1000 is recessed into the second surface S2 of the heat dissipation body 1. Furthermore, the cup-like structure 2 includes a bottom 20 and a curved structure 21 (as shown in FIG. 1, the cup-like structure 2 of a depth D is recessed into the second surface S2 of the heat dissipation body 1 of a thickness T). The curved structure 21 respectively connects the bottom 20 and the second surface S2 of the heat dissipation body 1, so that the junction of the curved structure 21 and the second surface S2 forms a contour 22, which is closed.

It is worth mentioning that, in the current embodiment, the curved structure 21 is a structure of a quarter arc, while the bottom 20 is a flat surface, and a shape thereof is substantially a circle. The curved structure 21 is connected to a periphery of the bottom 20, and the contour 22 formed by the curved structure 21 and the second surface S2 is a closed curved line, which is a circle in the current embodiment. However, this is not a limitation of the present invention. Depending on actual requirements, the curved line could be other geometric shapes.

In more detail, by providing one or more cup-like structures 2 on the second surface S2, a surface area of the second surface S2 of the heat dissipation body 1 would be increased. As a result, the heat dissipation effect of the heat dissipation body 1 could be enhanced. At the same time, the size and weight of the heat dissipation body 1 could be also decreased. As shown in FIG. 1, the surface area increased by each of the cup-like structures 2 provided in the present invention should be: a surface area of the cup-like structure 2 subtracts a surface area loss (i.e., an area occupied by the contour 22) of the second surface S2 caused by the cup-like structure 2. The calculation is as follows:

The surface area increased by each of the cup-like structures 2 can be calculated by subtracting the area occupied by the contour 22 from a sum of a surface area of the bottom 20 and a surface area of the curved structure 21. Take d for a diameter of the bottom 20, and take r for a radius of the curved structure 21, the relation satisfies the following formula:

$${( d / 2 )}^{2} * π + [ π dr + {r}^{2} π ] * \frac{π}{2} - {( d / 2 + r )}^{2} * π \qquad ( Formula 1 )$$

Wherein the surface area of the bottom 20 is: (d/2)^{2*}π;

the surface area of the curved structure 21 is: [πdr+r²π]*π/2;

the area occupied by the contour 22 is: (d/2+r)^{2*}π.

It is worth mentioning that the result of the calculation of Formula 1 is:

$$π * [ \frac{π}{2} dr + \frac{π}{2} {r}^{2} - dr - {r}^{2} ] \qquad ( Formula 2 )$$

Take π=3.14 as an example,

$$\frac{π}{2} dr$$

in Formula 2 is greater than dr, and

$$\frac{π}{2} {r}^{2}$$

is greater than r². Therefore, the result of Formula 2 is a positive value. In other words, compared to the situation that the heat dissipation body 1 has no cup-like structure 2 provided thereon, the design of the present invention which provides one or more cup-like structures 2 on the second surface S2 could indeed increase the surface area of the second surface S2 of the heat dissipation body 1, and the surface area increased by each of the cup-like structures 2 is expressed by Formula 2.

It could be seen from Formula 2, when the value of d is greater (i.e., when the bottom 20 is larger), the surface area increased by the cup-like structures 2 would become greater as well, which brings a better heat dissipation effect; when the value of r is greater (i.e., when the curved structure 21 has a greater radius), the surface area increased by the cup-like structures 2 would become greater as well, which also brings a better heat dissipation effect. In the current embodiment, for each of the cup-like structures 2, the radius r of the curved structure 21 equals the depth D, wherein the depth D of each of the cup-like structures 2 is limited by the thickness T of the heat dissipation body 1. Therefore, while taking the thickness T of the heat dissipation body 1 and the limitation for processing into consideration, cup-like structures 2 with a greater depth D (i.e., radius r) could provide a better heat dissipation effect.

Furthermore, if the heat dissipation body 1 has M cup-like structures 2 provided thereon, the surface area increased by the M cup-like structures 2 satisfies the following formula:

$$M * \{ π * [ \frac{π}{2} dr + \frac{π}{2} {r}^{2} - dr - {r}^{2} ] \} \qquad ( Formula 3 )$$

It could be seen from Formula 3, when the value of M is greater (i.e., when there are more cup-like structures 2 provided on the heat dissipation body 1), the surface area increased by the cup-like structures 2 is greater, which brings a better heat dissipation effect. In practice, the upper limit of the value of M (i.e., the greatest number of the cup-like structures 2 which could be possibly provided on the heat dissipation body 1) is determined by the limitation of processing.

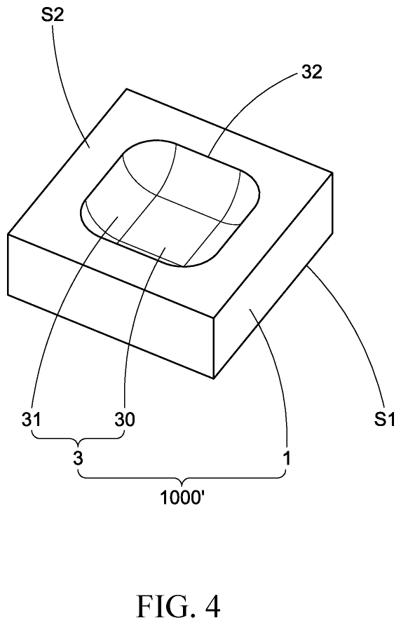

Part of a heat dissipation structure 1000′ of a second embodiment of the present invention is shown in FIG. 4. The heat dissipation structure 1000′ includes a heat dissipation body 1 and at least one cup-like structure 3. The heat dissipation body 1 has a first surface S1 and a second surface S2 opposite to the first surface S1, and the cup-like structure 3 is recessed into the second surface S2 of the heat dissipation body 1. The cup-like structure 3 includes a bottom 30 and a curved structure 31, wherein the curved structure 31 respectively connects the bottom 30 and the second surface S2 of the heat dissipation body 1, so that a junction of the curved structure 31 and the second surface S2 forms a contour 32, which is closed.

In design, the contour 32 is composed of N arcs and N straight lines, wherein two ends of each of the straight lines are respectively connected to one of the N arcs. N is a natural number greater than or equal to 3. In the current embodiment, the contour includes 4 arcs and 4 straight lines, wherein two ends of each of the straight lines are respectively connected to one of the 4 arcs, and the bottom 30 is a flat surface, which is substantially a rectangle. However, this is not a limitation of the present invention. In addition, the curved line could be other geometric shapes in other embodiments. For example, when N is 3, the shape of the contour 32 of the cup-like structure 3 is substantially a triangle; when N is 5, the shape of the contour 32 of the cup-like structure 3 is substantially a pentagon, and so on.

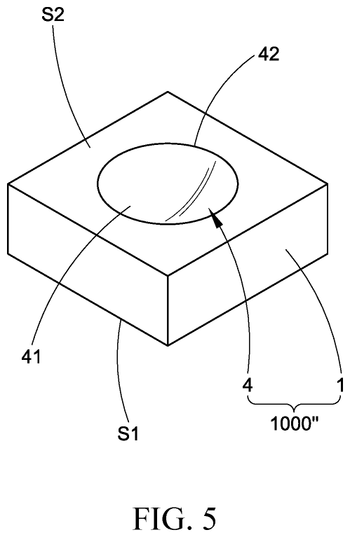

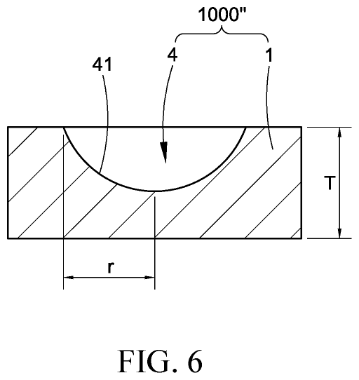

Part of a heat dissipation structure 1000″ of a third embodiment of the present invention is shown in FIG. 5, while FIG. 6 shows a sectional view of it. The heat dissipation structure 1000″ includes a heat dissipation body 1 and at least one cup-like structure 4. The heat dissipation body 1 includes a first surface S1 and a second surface S2 opposite to the first surface S1. The cup-like structure 4 is recessed into the second surface S2 of the heat dissipation body 1. The cup-like structure 4 includes a curved structure 41, so that a junction of the curved structure 41 and the second surface S2 of the heat dissipation body 1 forms a contour 42, which is closed.

In design, the cup-like structure 4 in the current embodiment is substantially a hemispherical structure, and the contour 22 formed by the junction of the curved structure 21 and the second surface S2 is a closed curved line, which is a circle. In addition, the current embodiment is different from the above embodiments by the fact that the cup-like structure 4 in the current embodiment only includes the curved structure 41, and has no bottom that is a flat surface.

In addition, a radius of the cup-like structure 4 (i.e., the hemispherical structure) is r, and a surface area increased by the cup-like structure 4 can be calculated by subtracting an area occupied by the contour 22, which is formed by the junction of the curved structure 21 and the second surface S2, from a surface area of the curved structure 41, and the result is:

2πr²−πr² (Formula 4)

It could be seen from Formula 4 that the result equals. Therefore, it could be learnt further from Formula 4, when the value of r (i.e., the radius of the cup-like structure 4) is greater, the heat dissipation effect would be better. In practice, the upper limit of the value of r (i.e., the radius of the cup-like structure 4) is determined by the limitation of processing. In other words, the greatest possible r which takes the thickness T of the heat dissipation body 1 and the limitation of processing into consideration would be the best parameter for the cup-like structure 4 in the current embodiment.

It needs to be clarified that, in addition to the variations of the above embodiments which engage the heat dissipation module 3000 with the electronic component, the heat dissipation structure 1000, 1000′, 1000″ could be also independently used in the electronic component 2000. In other words, it might not be mandatory to have the heat-conducting plate 5. In such an embodiment, the first surface S1 of the heat dissipation body 1 is directly coupled to the electronic component 2000. With such design, the cup-like structures 2, 3, 4 could still provide the effect of improving heat dissipation.

In summary, the heat dissipation structure 1000, 1000′, 1000″ provided in the present invention could be coupled to the electronic component 2000 either by combining the heat dissipation body 1 and the heat-conducting plate 5, or by simply coupling the heat dissipation body 1 to the electronic component 2000. Furthermore, with the design of the various kinds of the cup-like structures 2, 3, 4 in the above embodiments, the heat dissipation structures 1000, 1000′, 1000″ could effectively increase the performance of heat dissipation without increasing their volumes.

Compared to conventional techniques, the heat dissipation structure 1000, 1000′, 1000″ includes the heat dissipation body 1 and the cup-like structures 2, 3, 4, wherein the cup-like structures 2, 3, 4 are recessed into the second surface S2 of the heat dissipation body 1, and therefore would not increase the volume of the heat dissipation body 1. Furthermore, the size and weight could be even reduced. In this way, the present invention could increase the heat-dissipating surface area of the second surface S2 through the cup-like structures 2, 3, 4, so that to improve the heat dissipation effect of the heat dissipation body 1. At the same time, the size and weight of the heat dissipation body 1 could be also reduced whereby. Therefore, the heat dissipation structure 1000, 1000′, 1000″ provided in the present invention could be applied to all kinds of electronic products which are becoming thinner and smaller, whereby to effectively solve the disadvantage that the volume of protruding fins affects the looks of electronic products. It should be realized that the above description is only some preferred embodiments of the present invention and should not be deemed as limitations of implementing the present invention. All substantially equivalent variations and modifications which employ the concepts disclosed in this specification and the appended claims should fall within the scope of the present invention.

What is claimed is:

1. A heat dissipation structure adapted for an electronic component, comprising:
a heat dissipation body having a first surface and a second surface opposite to the first surface, wherein the first surface is adapted to couple with the electronic component; and
at least one cup-like structure formed on the second surface of the heat dissipation body, wherein the at least one cup-like structure comprises a bottom and a curved structure; the curved structure connects the bottom and the second surface of the heat dissipation body, wherein the curved structure forms a contour at a junction with the second surface, and the contour is closed.

2. The heat dissipation structure of claim 1, wherein the contour is a curved line.

3. The heat dissipation structure of claim 2, wherein the curved line is a circle.

4. The heat dissipation structure of claim 3, wherein the curved structure is substantially a structure of a quarter arc.

5. The heat dissipation structure of claim 4, wherein a shape of the bottom is substantially a circle.

6. The heat dissipation structure of claim 1, wherein the contour comprises N arcs and N straight lines; two ends of each of the straight lines are respectively connected to one of the arcs; N is a natural number greater than or equal to 3.

7. A heat dissipation structure adapted for an electronic component, comprising:
a heat dissipation body having a first surface and a second surface opposite to the first surface, wherein the first surface is adapted to couple with the electronic component; and
at least one cup-like structure formed on the second surface of the heat dissipation body, wherein the at least one cup-like structure is substantially a hemispherical structure.

8. A heat dissipation module adapted for an electronic component, comprising:
the heat dissipation structure mentioned in claim 1; and
a heat-conducting plate having a first side and a second side opposite to the first side, wherein the first side of the heat-conducting plate adheres to the first surface of the heat dissipation body, and the second side of the heat-conducting plate adheres to the electronic component.

9. The heat dissipation module of claim 8, further comprising a thermal adhesive, wherein the first side of the heat-conducting plate adheres to the first surface of the heat dissipation body through the thermal adhesive.

10. The heat dissipation module of claim 8, further comprising a thermal adhesive, wherein the second side of the heat-conducting plate adheres to the electronic component through the thermal adhesive.
